(19) United States
(12) Patent Application Publication
(10) Pub. No.: US 2013/0278111 A1
(43) Pub. Date: Oct. 24, 2013

(54) PIEZOELECTRIC MICROMACHINED ULTRASOUND TRANSDUCER WITH PATTERNED ELECTRODES

(71) Applicants: Masdar Institute of Science and Technology, Abu Dhabi (AE); Massachusetts Institute of Technology, Cambridge, MA (US)

(72) Inventors: Firas Sammoura, Melrose, MA (US); Katherine Marie Smyth, Cambridge, MA (US); Sang-Gook Kim, Wayland, MA (US)

(21) Appl. No.: 13/833,159

(22) Filed: Mar. 15, 2013

Related U.S. Application Data
(60) Provisional application No. 61/635,502, filed on Apr. 19, 2012.

(51) Int. Cl. H01L 41/047; H01L 41/09

(52) U.S. Cl. CPC H01L 41/047; H01L 41/09
USPC 310/317; 310/366

(57) ABSTRACT

A piezoelectric micro-machined ultrasonic transducer (PMUT) uses multiple electrodes, e.g., in a radial pattern for a disc, to improve performance. The multiple electrodes may be differentially driven to operate the PMUT in d₃₁ mode (that is, with an applied electrical field perpendicular to the piezoelectrically-induced strain) where deflection relative to input voltage is increased and in-plane stresses are reduce, thus improving overall performance.

### RELATED APPLICATIONS

This application claims the benefit of U.S. Prov. App. No. 61/635,502 filed on Apr. 19, 2012, the entire content of which is hereby incorporated by reference.

### BACKGROUND

Piezoelectric Micromachined Ultrasound Transducers (PMUTs) have emerged as a substitute to conventional ultrasonic sensors. A typical PMUT is a suspended membrane clamped at its edges and driven through piezoelectric effect by the application of an AC voltage. For instance, an air-coupled PMUT using Aluminum Nitride (AIN) as the active piezoelectric material is disclosed in Shelton, et al., “CMOS-Compatible AlN Piezoelectric Micromachined Ultrasonic Transducers,” 2009 IEEE International Ultrasonics Symposium (IUS), pp. 402-405, Rome, Italy, Sep. 20-23, 2009, incorporated by reference herein in its entirety. Other PMUTs have been demonstrated using, e.g., Lead Zirconate Titanate (PZT), which appears particularly promising in its Perovskite-phase due to a high degree of piezoelectric and ferroelectric coupling.

Thus, while a useful transducer may be micro-machined from Perovskite-phase PZT or other suitable material, there remains a need for improved PMUT structures that provide greater output power relative to applied voltage, greater dynamic range, and fewer harmonic artifacts.

### SUMMARY

A piezoelectric micro-machined ultrasonic transducer (PMUT) uses multiple electrodes, e.g., in a radial pattern for a disc, to improve performance. The multiple electrodes may be differentially driven to operate the PMUT in d₃₁ mode (that is, with an applied electrical field perpendicular to the piezoelectrically-induced strain) where deflection relative to input voltage is increased and in-plane stresses are reduced, thus improving overall performance.

### DRAWINGS

The invention may be more fully understood with reference to the accompanying drawings wherein:

FIG. 1 is a perspective drawing of an ultrasonic transducer.

FIG. 2 is cross-section of a prior art bimorph structure for a PMUT.

FIG. 3 is a cross-section of a two-electrode piezoelectric bimorph with an applied bias voltage.

FIG. 4 shows the piezoelectric moment in the device of FIG. 3.

FIG. 5 is a cross-section of a two-electrode piezoelectric bimorph with an applied bias voltage.

FIG. 6 shows the piezoelectric moment in the device of FIG. 5.

FIG. 7 is a cross-section of a multi-electrode PMUT with an applied bias voltage.

FIG. 8 shows the piezoelectric moment in the device of FIG. 7.

FIG. 9 shows the theoretical deflection of a bimorph structure with various numbers of electrodes.

FIG. 10 is an array of tunable ultrasound transducers.

### DETAILED DESCRIPTION

A variety of techniques are disclosed herein for constructing a multi-electrode Piezoelectric Micromachined Ultrasonic Transducer (PMUT) that can be differentially driven for improved performance. It will be appreciated that the following embodiments are provided by way of example only, and that numerous variations and modifications are possible. For example, while circular embodiments are shown, the PMUT may have a number of shapes such as a square, a hexagon, an octagon, and so forth. Similarly, while specific differential voltages are depicted, a variety of patterns of applied voltage may be used to drive a multi-electrode PMUT. Furthermore, while bimorph structures are generally illustrated, the PMUT may be a multimorph structure having a number of additional layers of piezoelectric material and electrodes. All such variations that would be apparent to one of ordinary skill in the art are intended to fall within the scope of this disclosure. It will also be appreciated that the following drawings are not necessarily to scale, with emphasis being instead on the distinguishing features of the multi-electrode transducers disclosed herein. Suitable dimensions for corresponding micromachined structures, and techniques for achieving same, may be readily ascertained by one of ordinary skill in the art.

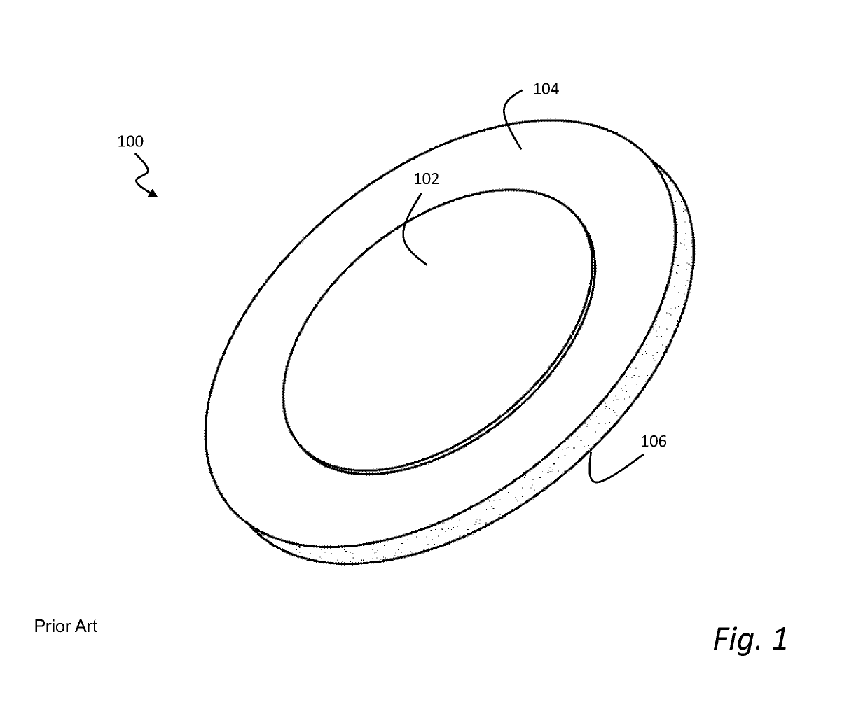

FIG. 1 is a perspective drawing of an ultrasonic transducer. In general, a Piezoelectric Micromachined Ultrasonic Transducer includes a cavity (not shown) covered by a flexible piezoelectric membrane such as the transducer 100 that deforms mechanically in response to an applied voltage or current. A typical transducer 100 may be disk-shaped with an outside diameter of about 100 μm, although it will be understood that a wide variety of shapes and sizes may also or instead be employed according to the intended use and/or operating frequency. For example, in medical ultrasound imaging, sizes from about 50 μm to about 250 μm may be used for operating frequencies from about 1 MHz to about 18 MHz. In general, the transducer 100 may include an electrode 102, a piezoelectric material 104, and a substrate 106.

The electrode 102 may be formed of copper, aluminum, or any other suitably conductive material for coupling the transducer 100 to a current or voltage supply.

The piezoelectric material 104 may be any material demonstrating sufficient piezoelectric response to serve in the ultrasound applications contemplated herein. In one aspect, the piezoelectric material 104 may include Lead Zirconate Titanate (PZT) in Perovskite-phase. Other piezoelectric materials suitable for micromachining include, e.g., other compositions of Lead Zirconate Titanate (in moncrystalline or polycrystalline forms), Aluminum Nitride, a piezoelectric ceramic bulk material, and so forth. More generally, any material or combination of materials having suitable piezoelectric response and amenable to micromachining or other incorporation into micro-electrical mechanical systems may be used as the piezoelectric material 104.

The substrate 106 may for example, be silicon in a bulk Silicon-on-Insulator wafer, or any other material suitable as a substrate for fabrication of micromachined components.

The transducer 100 may be fabricated using any of a variety of micromachining techniques including without limitation deposition, patterning, etching, silk-screening, and so forth. The variety of micromachining techniques for fabricating structures of silicon, polymers, metals, and ceramics are well known in the art, and may variously be employed according to the shape, dimensions, and material (or combination of materials) used in a particular transducer 100. In general, the transducer 100 may be clamped or otherwise supported about its perimeter to provide a cavity for vibration.

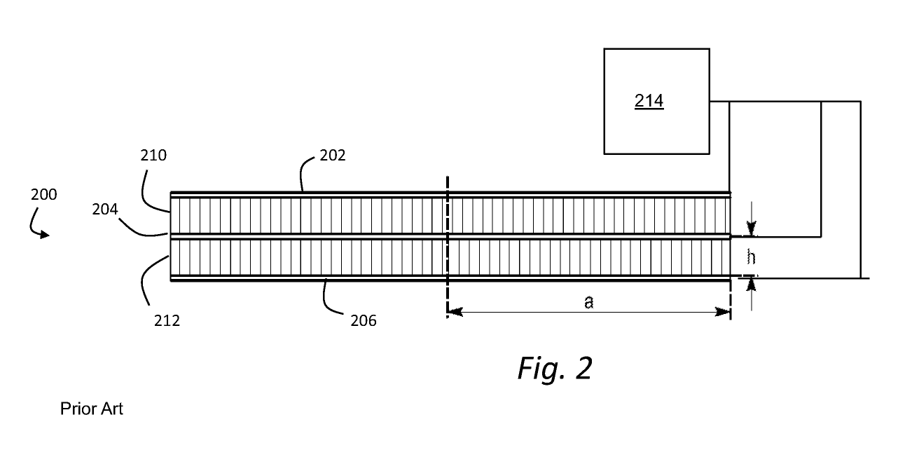

FIG. 2 is cross-section of a prior art bimorph structure for a PMUT. In general, the transducer 200 which may be a disk as illustrated above, or any other suitable two-dimensional shape, includes a first conductor 202, a second conductor 204, and a third conductor 206, which collectively surround a first piezoelectric material 210 and a second piezoelectric material 212. By way of distinguishing the PMUTs described below, it will be noted that each of the electrodes 202, 204, 206 is a single electrode covering substantially all of the adjacent piezoelectric material 210, 212.

Although not depicted, it will be understood that a transducer 200 is typically supported by a support structure to suspend the transducer 200 about a cavity or other chamber for resonant operation. The support structure may, for example, include one or more handles or similar structures of silicon or the like that support or “clamp” a substrate for the transducer 200. The substrate may include a number of layers such as a device layer formed of a bulk Silicon-on-Insulator wafer or other suitable material, along with an oxide or other etch stop or the like used to isolate fabrication of the support structure and other components during micromachining.

A voltage source 214 may be provided to drive the electrodes 202, 204, 206. In operation, the electrodes 202, 204, 206 may be driven to induce in-plane stresses in the transducer 200 with resulting deformations that create mechanical waves. By driving the electrodes 202, 204, 206 at ultrasonic frequencies, an ultrasonic wave can be produced. Similarly, when stresses are imposed on the transducer 200, e.g., by an incident ultrasonic wave, voltages will appear on the electrodes 202, 204, 206 from which the ultrasonic wave can be detected. In the figures that follow, the voltage source 214 (or alternatively, voltage sensor) is omitted for simplicity, with the voltage at each electrode illustrated for reference. Having described single electrode configurations of a PMUT bimorph, a number of multi-electrode configurations are now discussed in detail.

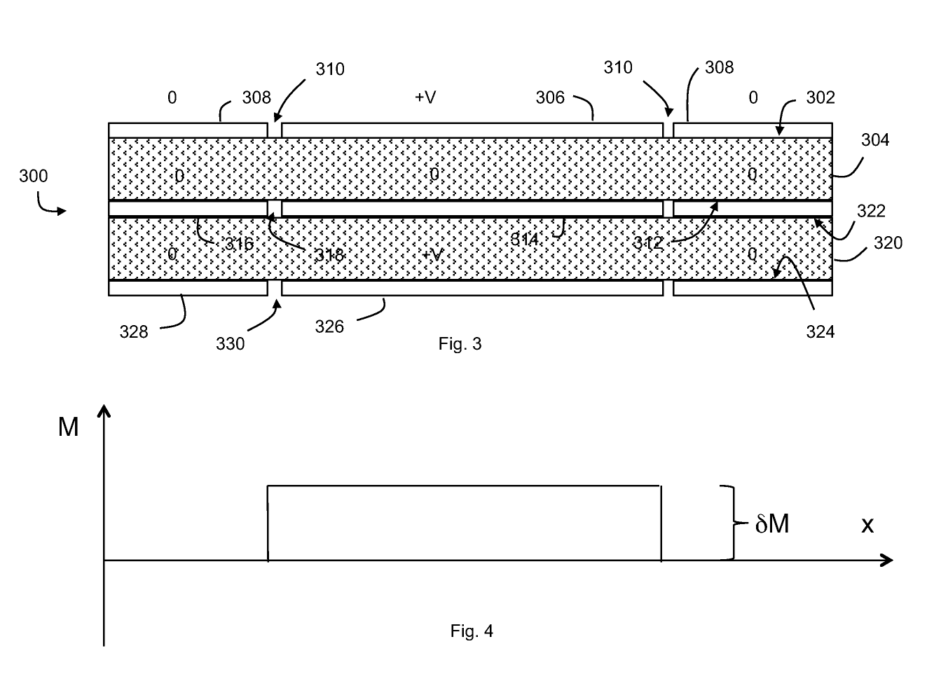

FIG. 3 is a cross-section of a two-electrode piezoelectric bimorph with an applied bias voltage. The transducer 300 may be a clamped, micromachined structure, and may include any suitable structure to support the transducer 300 over a cavity for resonation. In embodiments, the transducer 300 may have a resonant frequency of between one and eighteen Megahertz for use, e.g., in a medical ultrasound imaging device.

The transducer 300 may include a first group of (e.g., two or more) electrodes on a top surface 302 of a first piezoelectric material 304. The first group of electrodes may include a first electrode 306 centered on the top surface 302 and a second electrode 308 radially separated from the first electrode 306 by an insulation gap 310 to form a pattern on the top surface 302. A second group of electrodes may have a complementary arrangement on a bottom surface 312 of the first piezoelectric material 304, with a third electrode 314 centered on the bottom surface 312 and a fourth electrode 316 about the perimeter of the third electrode 314 and radially separated therefrom by an insulation gap 318 to form the same pattern on the bottom surface 312 as the first group of electrodes on the top surface 302.

The first piezoelectric material 304 may be formed as a disc (e.g., as illustrated in FIG. 1), with the first electrode 306 (and the third electrode 314) having a circular shape centered on the disc, and other electrodes forming annular rings concentrically arranged around the circular shape. Other geometries may also suitably be employed, and the first piezoelectric material may instead be a square, a hexagon, an octagon, or any other suitable shape.

While the principles disclosed herein may be suitably embodied in a unimorph structure having a single layer of piezoelectric material, bimorph and multimorph structures may also or instead be used. For a bimorph structure, a second piezoelectric material 320 with a top surface 324 and a bottom surface 326 is disposed beneath the second group of electrodes with the second top surface 324 adjacent to the second group of electrodes. It will be appreciated that the layers discussed herein need not be immediately adjacent, and there may be functional layers or trace materials disposed therebetween according to, e.g., the fabrication process used to micromachine the corresponding structures, without departing from the scope of this disclosure. A third group of electrodes on the bottom surface 326 of the second piezoelectric material 320 may have a complementary arrangement to the first and second group of electrodes, with a fifth 326 electrode centered on the bottom surface 324 and a sixth electrode 328 about the perimeter of the fifth electrode 326 and radially separated therefrom by an insulation gap 330 to form the same pattern as the first group of electrodes and the second group of electrodes.

A voltage source (not shown) may differentially drive the electrodes of the transducer 300 with a variety of patterns to induce in-plane stresses yielding desired deformation of the transducer 300. Resulting voltages (e.g., +V and 0 in FIG. 3) in an illustrative drive scenario are illustrated adjacent to the corresponding electrodes. For example, the voltage source may drive one of the first group of electrodes on the top surface 302 of the first piezoelectric material 304 at a substantially equal voltage to one of the third group of electrodes on the bottom surface 324 of the second piezoelectric material 320. Similarly, the voltage source may be configured to differentially drive one of the first group of electrodes and an opposing one of the second group of electrodes, such as the first electrode 306 on the top surface 302 of the first piezoelectric material and the third electrode 314 on the bottom surface 312 of the first piezoelectric material, which have complementary positions on the respective surfaces of the enveloped piezoelectric.

As noted above, a variety of suitable piezoelectric materials may be used as the first piezoelectric material 304 and/or the second piezoelectric material 320. For example, the piezoelectric material may include a Lead Zirconate Titanate (PZT), a Perovskite-phase PZT, a piezoelectric ceramic bulk material, or any other suitable material. For use in d₃₁ mode as generally contemplated herein, another suitable material is Aluminum Nitride, which may be poled as it is deposited to align dipole moments for use as a piezoelectric. Other materials may be poled during or after fabrication, or not require poling for use as a piezoelectric.

FIG. 4 shows the piezoelectric moment in the device of FIG. 3. Where a voltage is applied as illustrated in FIG. 3, it will be generally noted that the piezoelectric moment is substantially constant between the center electrodes.

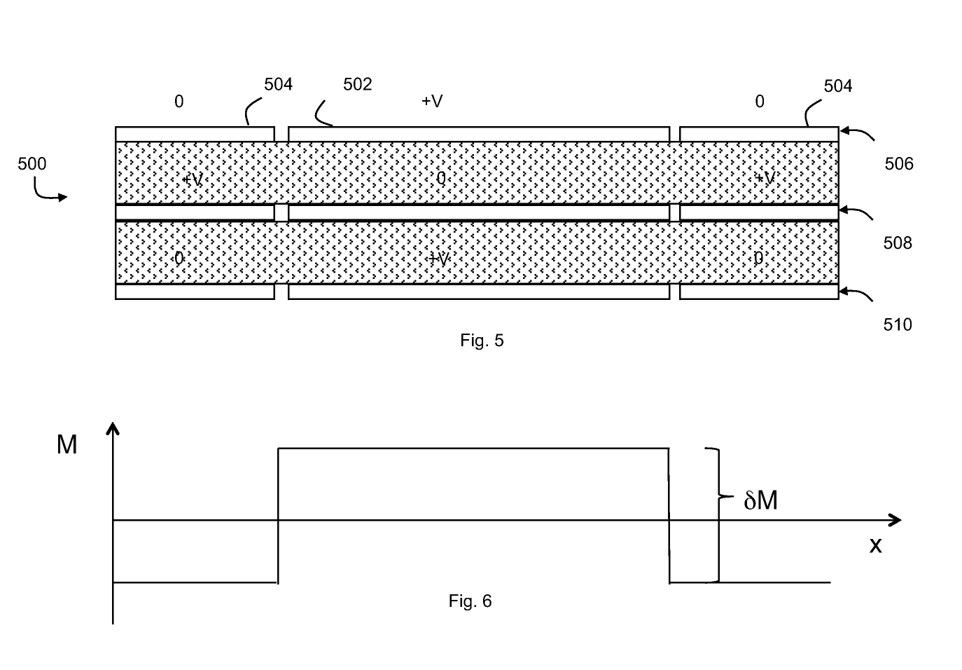

FIG. 5 is a cross-section of a two-electrode piezoelectric bimorph with an applied bias voltage. The transducer 500 may be similar in structure to the transducers described above. It will be noted that in FIG. 5, a voltage source (not shown) may be configured to differentially drive electrodes within each group of (coplanar) electrodes in addition to differentially driving complementary electrodes from top to bottom across each piezoelectric material. For example, it will be noted that adjacent ones 502, 504 of the electrodes on a top surface 506 of the first piezoelectric material may be differentially driven resulting in a pattern of applied voltages. More generally, the voltage source may be configured to differentially drive adjacent ones of the first group of electrodes 506 in the top plane, the second group of electrodes 508 in the middle plane, and the third group of electrodes 510 in the bottom plane in order to increase the aggregate piezoelectric moment across the transducer 500.

FIG. 6 shows the piezoelectric moment in the device of FIG. 5. It will be generally noted that the center area within the center electrodes has a first piezoelectric moment while the perimeter area within the perimeter electrodes has an opposing piezoelectric moment. This results in a greater physical displacement of the transducer relative to the transducer as driven in FIG. 3.

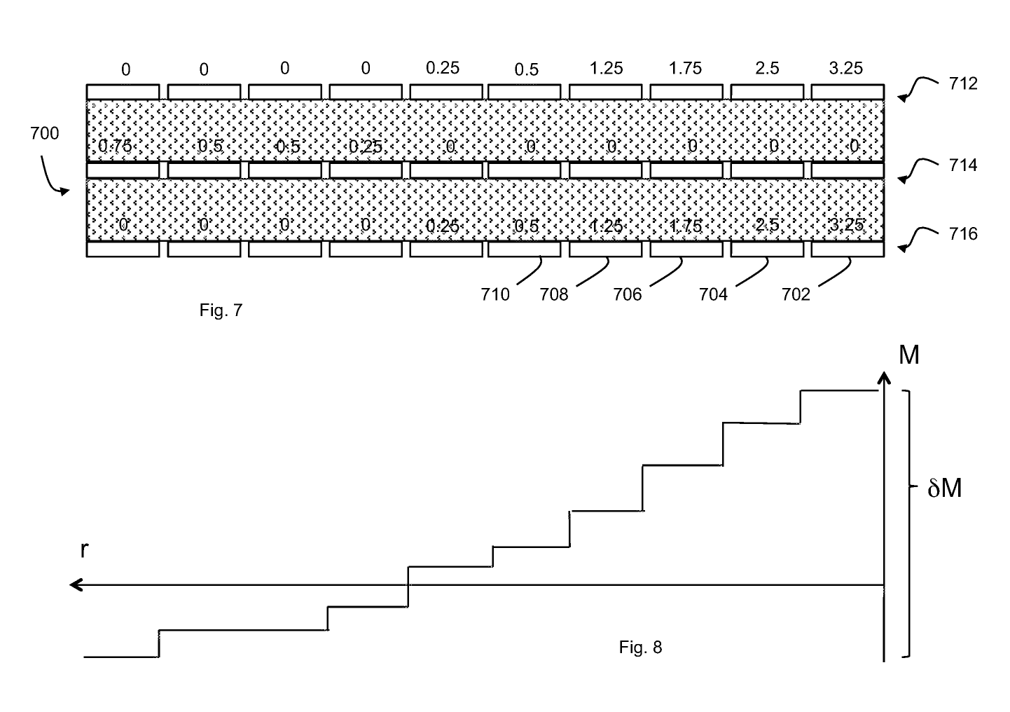

FIG. 7 is a cross-section of a multi-electrode PMUT with an applied bias voltage. As illustrated by the transducer 700 in FIG. 7, the principles described above may be generalized to any number of concentric, radial electrodes. In FIG. 7, one half of the cross-section is illustrated with a group of electrodes including a center electrode 702 and a number of additional electrodes 704, 706, 708, 710, etc. that form a number of concentric rings about the center electrode 702, separated from one another by a corresponding number of gaps. In general, this group of electrodes may include three electrodes, four electrodes, or any number of electrodes subject to practical limits on processes used to fabricate the transducer 700 and related circuitry to differentially drive adjacent electrodes. Complementary patterns of electrodes for a second group, a third group, and so forth may be fabricated along with additional layers of piezoelectric material to create a bimorph structure (as shown) or a multimorph structure including three or more piezoelectric layers.

In general, a variety of differential driving schemes for voltage may be used. An exemplary pattern is illustrated in FIG. 7 with a voltage varying from a high of 3.25 V at a center electrode of a first group of electrodes in a top layer 712 out to zero V at a perimeter electrode. In complementary fashion, a second layer 714 of electrodes in a second group has a voltage of 0.75 V at a perimeter progressing to zero V at the center electrode. A bottom layer 716 with a third group of electrodes repeats the voltage pattern of the top layer 712. Thus a voltage source (not shown) may be configured to drive each one of three or more electrodes in a layer at a substantially different voltage ranging, e.g., from zero to 3.25 V, or from 0 V to a maximum voltage available for a voltage source. The voltage source may also or instead drive two or more of the electrodes in a layer at a substantially equal voltage. For example, a central electrode and a number of adjacent electrodes may be driven at 0 V (such as in the second layer 714), or a perimeter electrode and a number of adjacent electrodes may be driven at 0 V (such as the first layer 712 and the third layer 713).

FIG. 8 shows the piezoelectric moment in the device of FIG. 7. More specifically, FIG. 8 illustrates a customized moment/strain profile for the transducer 7 of FIG. 7 when differentially driven as indicated. By changing or inverting the edge electrical field at each boundary between electrodes, a substantial cumulative deflection may be achieved even where a voltage source is limited to 0-3.25 V or some other similar range suitable for micromachined electronics as contemplated herein.

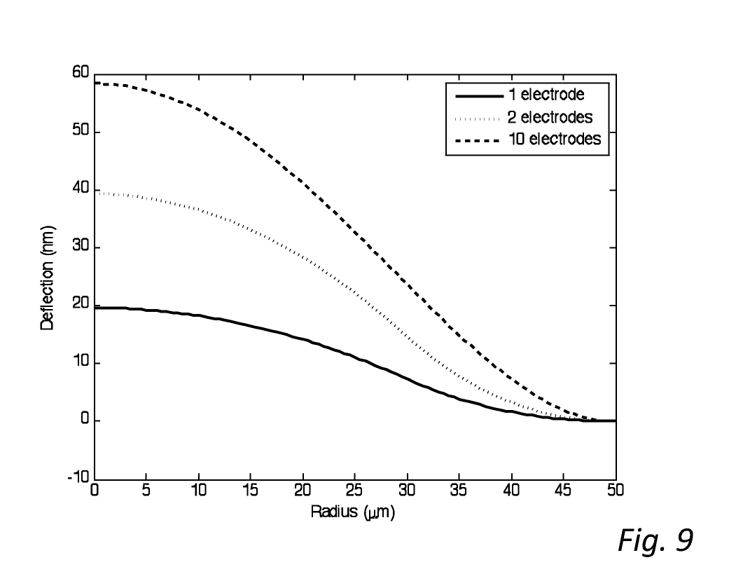

FIG. 9 shows theoretical deflection of a bimorph structure with various numbers of electrodes. The corresponding analytical development for calculating deflection in a disc shaped PMUT is provided below in order to illustrate the improved deflection that can be achieved with a multi-electrode configuration.

Where the lateral dimensions of the proposed PMUT will be much larger than the thickness, classic plate theory is appropriate to describe the shape profile and vibration modes. Axisymmetric plate vibration is assumed due to the rotational symmetry of the applied electric field and the mechanical acoustic pressure.

The residual stress σ_{0,i} in each layer is related to the processing conditions of each film and is assumed to be constant in both the radial and theta-direction. Since all the layers have the same radius b, the overall plate tension T^{s} (force per unit length) caused by the residual stresses σ_{0,i} (for a number of layers of thickness hᵢ) is:

$${T}^{s} = {\sum }_{i = 1}^{n} {σ}_{0 , i} {h}_{i} \qquad [ Eq . 1 ]$$

For a plate subject to residual stress, the residual tension or compression in [Eq. 1] affects the overall deflection of the stressed plate. Based on the stressed plate equation, a critical stress N_{cr} can be derived, at which the plate will buckle losing all load bearing capability:

$${N}_{cr} = 14.66 \frac{D}{{b}^{2}} \qquad [ Eq . 2 ]$$

where D is the modulus of flexual rigidity defined as:

$$D = {\sum }_{i = 1}^{n} {Y}_{0 , i}^{′} [ {I}_{i} + {Z}_{i}^{2} {h}_{i} ] \qquad [ Eq . 3 ]$$

The axial elastic stiffness coefficient, the second moment of inertia, and the distance from the neutral axis zₘ to the center zᵢ of the i^{th} layer are designtated as Y_{0,i}′, Iⁱ, and Zᵢ, respectively:

$$\begin{matrix}{Y}_{0 , i}^{′} = {Y}_{0 , i} / ( 1 - {v}_{i}^{2} ) & [ Eq . 4 ] \\ {I}_{i} = {h}_{i}^{3} / 12 & [ Eq . 5 ] \\ {Z}_{i} = {z}_{i} - {z}_{m} ; \\ {z}_{m} = [ {\sum }_{i = 1}^{n} {Y}_{0 , i}^{′} {z}_{i} {h}_{i} ] / [ {\sum }_{i = 1}^{n} {Y}_{0 , i}^{′} {h}_{i} ] & [ Eq . 6 ]\end{matrix}$$

It has been noted that the moment imbalance about the moment neutral axis zₘ might also cause buckling and for lesser imbalances could adversely affect deflection. The residual moment M^{s} around zₘ is calculated through the thickness of the plate for an arbitrary number of plate layers n:

$${M}^{s} = {\sum }_{i = 1}^{n} {\int }_{{Z}_{i - 1}}^{{Z}_{i}} {σ}_{0 , i} z d z = {\sum }_{i = 1}^{n} {σ}_{o , i} {Z}_{i} {h}_{i} \qquad [ Eq . 7 ]$$

For a patterned top electrode configuration, the residual moment due to the top electrode with residual stress σ_{0,Pt} exists only in the region covered by the top electrode. The modified residual stress moment Mₘ^{s} becomes:

$${M}_{m}^{s} = {\sum }_{i = 1}^{n} {σ}_{0 , i} {Z}_{i} {h}_{i} + {M}_{Pt}^{s} {\sum }_{i = 1}^{m} [ H ( r - {a}_{j}^{′} ) - H ( r - {a}_{j}^{″} ) ] \qquad [ Eq . 8 ]$$

where, aⱼ′ is the inner radius of an electrode, aⱼ″ is the outer radius of the electrode, and M_{Pt}^{s}=σ_{0,Pt}Z_{Pt}h_{Pt}. The voltage requirement is dependent on the piezoelectric moment and thus the voltage requirement alone can be used to define the appropriate piezoelectric moment. The piezoelectric moment is present in transmit mode when a voltage is applied across the plate causing deformation. A radial tension is caused by the applied voltage that acts along the center of the PZT layer resulting in an applied piezoelectric moment M^{p} about the moment neutral axis. Assuming the piezoelectric material is only located at the PZT layer, the piezoelectric moment is:

M^{p}=Y_{0,PZT}′d_{31,PZT}′Z_{PZT}V [Eq. 9]

where d′_{31,PZT} is the modified transverse piezo-strain coefficient of the PZT layer, which is related to the transverse piezo-strain coefficient d_{31,PZT} as:

d_{31,PZT}′=(1+ν_{PZT})d_{31,PZT} [Eq. 10]

In an arbitrary ring electrode configuration, the PZT layer will be excited in areas beneath each electrode, so the piezoelectric moment is only valid in the region covered by an electrode; otherwise, the applied piezoelectric moment is zero. For the above equation to be universally valid for the arbitrary electrode case, the modified piezoelectric applied moment Mₘ^{p} is defined by a series of step functions:

$${M}_{m}^{p} = {M}^{p} {\sum }_{i = 1}^{m} [ H ( r - {a}_{j}^{′} ) - H ( r - {a}_{j}^{″} ) ] \qquad [ Eq . 11 ]$$

PMUT's dynamically receive and transmit pressure waves during operation. The plate deflection equation is a boundary value problem with a forcing function ƒ(r) that varies radially:

$${∇}^{2} {∇}^{2} w - \frac{{T}^{s}}{D} {∇}^{2} w + \frac{{ρ}_{s}}{D} \frac{{\partial }^{2} w}{\partial {t}^{2}} = f ( r ) \qquad [ Eq . 12 ]$$

where ρₛ is the area plate density and the forcing functions are defined as:

$$\begin{matrix}{ρ}_{s} = {\sum }_{i = 1}^{n} {ρ}_{i} {h}_{i} & [ Eq . 13 ] \\ f ( r ) = \frac{1}{D} ( q + {∇}^{2} {M}_{m}^{p} + {∇}^{2} {M}_{m}^{s} ) & [ Eq . 14 ]\end{matrix}$$

where q is the acoustic pressure. The second and third terms of ƒ(r) are the equivalent forces due to converse piezoelectricity and internal residual stresses, respectively.

Under axisymmetric harmonic excitation with angular frequency ω=2πƒ, the deflection can be assumed to take the form w(r,t)=W(r)e^{jωt}, where W(r) describes the contour of the plate during vibration. For a clamped plate of radius b, the boundary conditions W(b)=0 and W′(b)=0 need to be satisfied. The overall solution to the homogeneous vibration equation is a set of characteristic functions Ψₖ(r) that fulfill the necessary boundary conditions:

$${Ψ}_{k} ( r ) = {J}_{0} ( \frac{{πα}_{k}}{b} r ) - \frac{{J}_{0} ( {πα}_{k} )}{{I}_{0} ( {πβ}_{k} )} {I}_{0} ( \frac{{πβ}_{k}}{b} r ) \qquad [ Eq . 15 ]$$

where k is the radial mode shape number. The constants αₖ and βₖ depend on the vibration mode and can be numerically determined from the boundary conditions provided by [Eq. 12], along with the following identities:

$$\begin{matrix}{β}_{k}^{2} - {α}_{k}^{2} = \frac{{T}^{s} {b}^{2}}{{π}^{2} D} & [ Eq . 16 ] \\ {α}_{k} {I}_{0} ( {πβ}_{k} ) {J}_{1} ( {πα}_{k} ) + {β}_{k} {J}_{0} ( {πα}_{k} ) {I}_{1} ( {πβ}_{k} ) = 0 & [ Eq . 17 ]\end{matrix}$$

To broaden the applicability of this homogeneous solution, a force applied at a point r₀ is now considered driving the steady-state plate motion. The solution of the resulting heterogeneous equation is the Green's function G(r|r₀):

$$( {∇}^{2} + {α}^{2} ) ( {∇}^{2} - {β}^{2} ) G ( r \vert {r}_{0} ) = \frac{1}{r} δ ( r - {r}_{0} ) \qquad [ Eq . 18 ]$$

where α and β are constants that depend on the material properties and the excitation frequency. They can be calculated using [Eq. 12] and [Eq. 18] as:

$$\begin{matrix}{α}^{2} = \frac{- {T}^{s} + \sqrt{{( {T}^{s} )}^{2} + 4 D {ρ}_{s} {ω}^{2}}}{2 D} & [ Eq . 19 ] \\ {β}^{2} = \frac{{T}^{s} + \sqrt{{( {T}^{s} )}^{2} + 4 D {ρ}_{s} {ω}^{2}}}{2 D} & [ Eq . 20 ]\end{matrix}$$

The Green's function can be expressed as a series of the characteristic functions of the homogeneous vibration equation as:

$$G ( r \vert {r}_{0} ) = {\sum }_{k} {A}_{k} {Ψ}_{k} ( r ) \qquad [ Eq . 21 ]$$

The constants Aₖ of each characteristic function can be determined by substituting [Eq. 21] into [Eq. 18] and multiplying by Ψₖ(r)rdr and integrating over the plate area. Since the characteristic functions are orthogonal, the Green's function becomes:

$$\begin{matrix}G ( r \vert {r}_{0} ) = {\sum }_{k} \frac{{Ψ}_{k} ( r ) {Ψ}_{k} ( {r}_{0} )}{{Λ}_{k} [ {( {πα}_{k} / b )}^{2} + {β}^{2} ] [ {( {πα}_{k} / b )}^{2} - {α}^{2} ]} & [ Eq . 22 ] \\ {Λ}_{k} = {\int }_{0}^{b} {[ {Ψ}_{k} ( r ) ]}^{2} r d r & [ Eq . 23 ]\end{matrix}$$

The vibration equation can now be solved using the properties of the Green's function. First, [Eq. 12] is multiplied by G (r|r₀) and [Eq. 18] is multiplied by W(r). The modified equations are then subtracted from each other and integrated over the plate area. In axisymmetric plate vibration, maximum deflection occurs at the center of the plate; therefore, it can be assumed that W′(0)=0. Upon integrating by parts with the assumption of zero-slope at the center and clamped boundary conditions, the plate deflection becomes:

$$W ( r ) = {\int }_{0}^{b} {r}_{0} f ( {r}_{0} ) G ( r \vert {r}_{0} ) d {r}_{0} \qquad [ Eq . 24 ]$$

Upon carrying out the integration in [Eq. 13] using [Eq. 14] and [Eq. 22], the plate displacement can be explicitly found for an impinging acoustic pressure W_{q}(r), applied voltage Wₚ(r), and residual stress in the top electrode Wₛ(r) for an arbitrary electrode configuration:

$$\begin{matrix}{W}_{q} ( r ) = \frac{q {b}^{2}}{π D} {\sum }_{k = 1}^{∞} \frac{[ \frac{{J}_{1} ( π {α}_{k} )}{{α}_{k}} - \frac{{J}_{0} ( {πα}_{k} )}{{β}_{k} {I}_{0} ( {πβ}_{k} )} {I}_{1} ( {πβ}_{k } ) ]}{{Λ}_{k} [ {( {πα}_{k} / b )}^{2} + {β}^{2} ] [ {( {πα}_{k} / b )}^{2} - {α}^{2} ]} {Ψ}_{k} ( r ) & [ Eq . 25 ] \\ {W}_{p} ( r ) = \frac{π {M}^{p}}{b D} {{\sum }_{j = 1}}^{m} {\sum }_{k = 1}^{∞} \frac{{O}_{k} ( {a}_{j}^{′} ) - {O}_{k} ( {a}_{j}^{* } )}{{Λ}_{k} [ {( {πα}_{k} / b )}^{2} + {β}^{2} ] [ {( {πα}_{k} / b )}^{2} - {α}^{2} ]} {Ψ}_{k} ( r ) & [ Eq . 26 ] \\ {W}_{s} ( r ) = \frac{π {M}_{Pt}^{s}}{b D} {{\sum }_{j = 1}}^{m} {\sum }_{k = 1}^{∞} \frac{{O}_{k} ( {a}_{j}^{′} ) - {O}_{k} ( {a}_{j}^{* } )}{{Λ}_{k} [ {( {πα}_{k} / b )}^{2} + {β}^{2} ] [ {( {πα}_{k} / b )}^{2} - {α}^{2} ]} {Ψ}_{k} ( r ) & [ Eq . 27 ]\end{matrix}$$

where Oₖ(x) is defined as:

$${O}_{k} ( x ) = x [ {α}_{k} {J}_{1} ( \frac{{πα}_{k}}{b} x ) + {β}_{k} \frac{{J}_{0} ( {πα}_{k} )}{{I}_{0} ( {πβ}_{k} )} {I}_{1} ( \frac{{πβ}_{k}}{b} x ) ] \qquad [ Eq . 28 ]$$

Finally, for n vibration modes, N electrodes, a bimorph deflection solution can be calculated as:

$$\begin{matrix}W ( {r}_{0} ) = \frac{{M}_{p}}{{a}^{3} D} {\sum }_{n} {\sum }_{k = 1}^{N} \frac{{β}_{0 n}}{{Λ}_{0 n} ( {γ}_{0 n}^{4} - {γ}^{4} )} ( {J}_{0} ( \frac{{πβ}_{0 n} {r}_{0}}{a} ) - \frac{{J}_{0} ( {πβ}_{0 n} )}{{I}_{0} ( {πβ}_{0 n} )} {I}_{0} ( \frac{{πβ}_{0 n} {r}_{0}}{a} ) ) [ \begin{matrix}{a}_{k}^{′} ( {J}_{1} ( \frac{{πβ}_{0 n} {a}_{k}^{′}}{a} ) + \frac{{J}_{0} ( {πβ}_{0 n} )}{{I}_{0} ( {πβ}_{0 n} )} {I}_{1} ( \frac{{πβ}_{0 n} {a}_{k}^{′}}{a} ) ) - \\ {a}_{k}^{″} ( {J}_{1} ( \frac{{πβ}_{0 n} {a}_{k}^{″}}{a} ) + \frac{{J}_{0} ( {πβ}_{0 n} )}{{I}_{0} ( {πβ}_{0 n} )} {I}_{1} ( \frac{{πβ}_{0 n} {a}_{k}^{″}}{a} ) )\end{matrix} ] & [ Eq . 29 ] \\ where \text{:} & \\ {I}_{0} = {ρ}_{PZT} {h}_{PZT} & [ Eq . 30 ] \\ D = \frac{{Y}_{PZT} {h}_{PZT}^{2}}{12 ( 1 - {v}_{PZT}^{2} )} \\ and & [ Eq . 31 ] \\ {γ}^{4} = \frac{{ω}^{2} {I}_{0}}{D} & [ Eq . 32 ]\end{matrix}$$

While the analytical framework is complex, it yields important insights about the use of multi-electrode arrangements to drive deflection in a PMUT structure. In particular, using suitable constants, deflection as a function of radius can be calculated as shown in FIG. 9, where analytical solutions are shown for one electrode, two electrodes, and ten electrodes. It will be noted that increasing from one electrode to two electrodes increases maximum deflection at the center (radius=0) by about a factor of two from about 20 nm to about 40 nm for a 100 μm disc. An increase from one electrode to ten electrodes increases the maximum deflection by about a factor of three. The analytical solution provides additional insights. For example, while a variety of radial spacings are possible, it can be determined from the above deflection solution that relatively good performance can be achieved where the electrodes cover about thirty-six percent of the top area of the piezoelectric material, or where the electrodes cover about sixty percent of the radius of the piezoelectric material. Behavior of actual bimorphs has been demonstrated to conform to the theoretical development above.

Additional advantages accrue to a multi-electrode bimorph. As a significant advantage, the more uniform deflection of the multi-electrode bimorph produces less harmonic noise, which improves harmonic imaging. In addition, as noted above, greater deflection per unit of applied voltage can be achieved, along with a reduction of internal stresses, providing a more efficient ultrasound transducer with fewer acoustic artifacts arising from deflection of the bimorph structure.

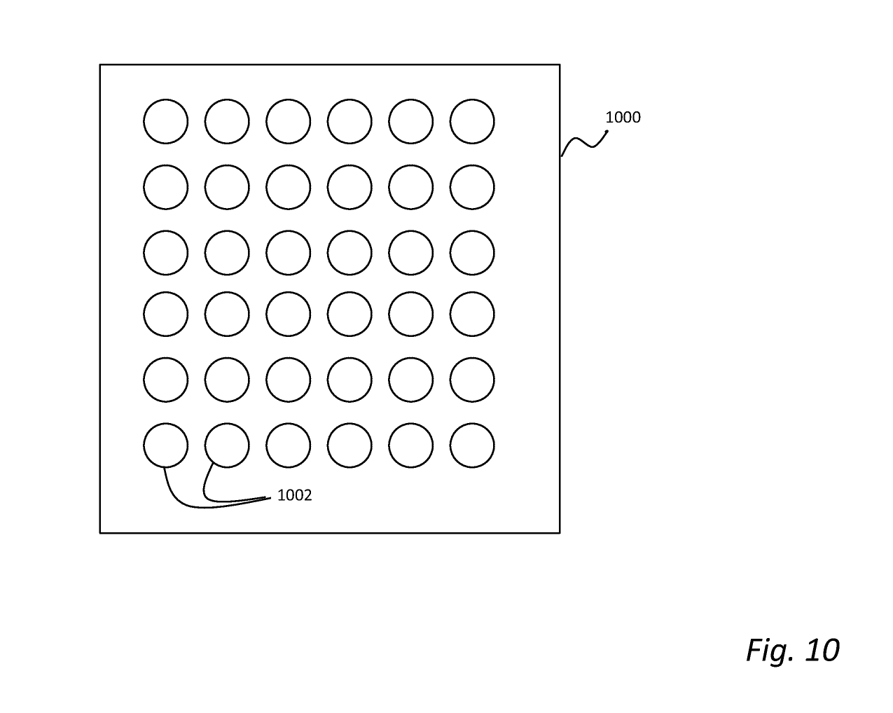

FIG. 10 shows an array of tunable ultrasound transducers. The array 1000 may include a plurality of transducers 1002 arranged on any suitable substrate, each coupled to a support structure such as any of the support structures described above and each including a multi-electrode configuration for improved performance. The transducers 1002 may be independently driven or commonly driven or some combination of these according to an intended use of the array. Similarly, different groups of the transducers 1002 may also have different sizes, shapes, and numbers of electrodes. Thus, a variety of arrays of ultrasonic transducers may be usefully fabricated, either in a single micromachining process or in a number of different micromachining processes to provide an array of ultrasonic transducers.

It will be appreciated that the methods and systems described above are set forth by way of example and not of limitation. Numerous variations, additions, omissions, and other modifications will be apparent to one of ordinary skill in the art. While particular embodiments of the present invention have been shown and described, it will be apparent to those skilled in the art that various changes and modifications in form and details may be made therein without departing from the spirit and scope of the invention as defined by the following claims. The claims that follow are intended to include all such variations and modifications that might fall within their scope, and should be interpreted in the broadest sense allowable by law.

What is claimed is:

1. A device formed of a clamped, micromachined structure, the device comprising:
a piezoelectric material having a top surface and a bottom surface;
a first group of electrodes forming a pattern on the top surface of the first piezoelectric material; and
a second group of electrodes forming the pattern on the bottom surface of the first piezoelectric material.

2. The device of claim 1 wherein the piezoelectric material is a disc.

3. The device of claim 2 wherein the first group of electrodes includes a first electrode having a circular shape centered on the disc.

4. The device of claim 1 wherein the piezoelectric material has a perimeter shape selected from a group consisting of a square and a hexagon.

5. The device of claim 1 wherein the first group of electrodes forms a number of concentric rings separated by a corresponding number of gaps.

6. The device of claim 1 wherein the first group of electrodes includes three or more electrodes.

7. The device of claim 6 further comprising a voltage source configured to drive each one of the three or more electrodes at a substantially different voltage.

8. The device of claim 6 further comprising a voltage source that drives at least two of the three or more electrodes at a substantially equal voltage.

9. The device of claim 8 wherein the substantially equal voltage is about zero Volts.

10. The device of claim 1 further comprising a voltage source configured to differentially drive adjacent ones of the first group of electrodes.

11. The device of claim 1 further comprising a voltage source configured to differentially drive one of the first group of electrodes and an opposing one of the second group of electrodes.

12. The device of claim 1 wherein the piezoelectric material is not initially poled.

13. The device of claim 1 wherein the piezoelectric material is poled Aluminum nitride.

14. The device of claim 1 further comprising a silicon substrate.

15. The device of claim 1 wherein the clamped, micromachined structure includes a support structure.

16. The device of claim 1 wherein the piezoelectric material includes a Lead Zirconate Titanate (PZT).

17. The device of claim 1 wherein the PZT is Perovskite-phase PZT.

18. The device of claim 1 wherein the piezoelectric material includes a piezoelectric ceramic bulk material.

19. The device of claim 1 wherein the clamped, micromachined structure is an ultrasound transducer having a resonant frequency of between one and eighteen Megahertz.

20. The device of claim 1 wherein the first group of electrodes covers about thirty-six percent of a top area of the piezoelectric material.

21. The device of claim 1 wherein the first group of electrodes cover about sixty percent of a radius of the piezoelectric material.

22. The device of claim 1 further comprising:
a second piezoelectric material having a second top surface and a second bottom surface, the second top surface adjacent to the second group of electrodes; and
a third group of electrodes forming the pattern on the second bottom surface of the second piezoelectric material.

23. The device of claim 22 further comprising a voltage source that drives one of the third group of electrodes and a corresponding one of the first group of electrodes at a substantially equal voltage.
